(19) United States
(12) Patent Application Publication
(10) Pub. No.: US 2024/0105788 A1
(43) Pub. Date: Mar. 28, 2024

(54) LOCAL INTERCONNECT AT BACKSIDE TO ENABLE FLEXIBLE ROUTING ACROSS DIFFERENT CELL

(71) Applicant: INTERNATIONAL BUSINESS MACHINES CORPORATION, ARMONK, NY (US)

(72) Inventors: Ruilong Xie, Niskayuna, NY (US); Tsung-Sheng Kang, Ballston Lake, NY (US); Daniel Schmidt, Niskayuna, NY (US); Alexander Reznicek, Troy, NY (US)

(21) Appl. No.: 17/935,928

(22) Filed: Sep. 27, 2022

(51) Int. Cl. H01L 29/417; H01L 21/768; H01L 23/528; H01L 29/40

(52) U.S. Cl. CPC H01L 29/41766; H01L 21/768; H01L 23/5286; H01L 29/401

(57) ABSTRACT

A semiconductor device includes a wafer having at least two source/drain (S/D) epi regions. A power rail is arranged on a backside of the wafer. A backside contact (BSCA) has a first portion including a backside local interconnect configured to connect the S/D epi regions together. A plurality of frontside signal wires are connected to the backside local interconnect through a first front side contact.

### BACKGROUND

### Technical Field

The present disclosure generally relates to the miniaturization of semiconductor devices, and more particularly, to a method and structure of increasing the use of signal tracks in semiconductor devices.

### Description of the Related Art

As the cell height of semiconductor devices is scaled, the number of available signal tracks in a logic cell is reduced. Accordingly, the use of signal tracks in neighboring cells has been discovered as a way to compensate for the reduction in available signal tracks. Local interconnects at the backside of a wafer may be configured for use of such neighboring signal tracks.

### SUMMARY

According to one embodiment, a semiconductor device includes a wafer having at least two source/drain (S/D) epi regions. A power rail is arranged on a backside of the wafer. A backside contact (BSCA) has a first portion including a backside local interconnect with a recessed surface and is configured to connect the S/D epi regions together. A plurality of frontside signal wires are connected to the backside local interconnect through a first front side contact.

In one embodiment, the BSCA has a second portion connected to the backside power rail.

In one embodiment, a surface of the backside local interconnect is lower than a surface of the second portion of the BSCA to insulate the backside local interconnect from the power rail.

In one embodiment, a height of the recessed surface of the backside local interconnect is lower than a surface of a buried oxide (BOX) layer adjoining a side of the BSCA.

In one embodiment, the recessed surface of the backside local interconnect has a backside interlayer dielectric (BILD) formed thereon.

In one embodiment, at least one S/D epi region connected to the backside local interconnect is overlapped with a second frontside contact extension of a device from a neighboring cell.

In one embodiment, the second frontside contact extension is wired to signal tracks over the S/D/region with the backside local interconnect.

In one embodiment, a backside power distribution network (BSPDN) is connected to the backside power rail.

In one embodiment, at least one S/D epi region connected to the backside local interconnect is an S/D P-epi region and an S/D N-epi region.

In one embodiment, the S/D N-epi region or the S/D P-epi region is electrically connected to the frontside contact.

According to one embodiment, a method of forming a semiconductor device includes forming on a wafer a sacrificial placeholder under a Source/Drain (S/D) epi, which connects to more than one S/D epi region. A frontside contact is formed to wire the S/D epi regions to a Back End Of Line (BEOL) interconnect with a contact width smaller than the sacrificial placeholder. A BEOL interconnect is formed and a bonding a carrier wafer is bonded to the BEOL interconnect. The wafer is flipped and substrate is removed. The sacrificial placeholder is removed and a backside contact metallization is formed on the wafer. A first portion of the backside contact is recessed to prevent contact with a backside power distribution network.

According to one embodiment, the method further includes connecting a second portion of the backside contact to a backside power rail connected to the backside power distribution network.

According to one embodiment, the method further includes recessing the first portion of the backside contact so that its surface is lower than a surface of the second portion of the backside contact and insulated from the power rail, and the second portion of the backside contact is electrically connected to the backside power rail.

According to one embodiment, the method further includes forming a backside interlayer dielectric (BILD) on the recessed surface of the first portion of the backside contact.

According to one embodiment, the method further includes connecting at least one S/D epi region to overlap with a second frontside contact extension of a device from a neighboring cell.

According to one embodiment, the method further includes wiring the second frontside contact extension to signal tracks over the S/D region with the backside contact.

According to one embodiment, the method further includes connecting the backside power distribution network to the backside power rail.

According to one embodiment, the method further includes connecting the at least one S/D epi region to the backside contact local interconnect comprises connecting at least one of an S/D P-epi region and an S/D N-epi region.

According to one embodiment, the method further includes connecting one of the S/D N-epi region or the S/D P-epi region to the first frontside contact.

According to one embodiment, the method further includes forming a capping dielectric on the wafer after removing the sacrificial placeholder.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 provides an overview of a semiconductor device, consistent with an illustrative embodiment.

FIG. 2 is a flowchart illustrating a method of forming semiconductor device, consistent with respective illustrative embodiments.

FIG. 3 illustrates a starting wafer used in a process flow of forming a semiconductor, consistent with an illustrative embodiment.

FIG. 4A is a cross-sectional view of a nanosheet patterning and hard mask removal from the wafer, consistent with an illustrative embodiment.

FIG. 4B shows a top view identifying the cross-section (Y1) shown in FIG. 4A, consistent with an illustrative embodiment.

FIGS. 5A, 5B, and 5C are cross-sectional views of the wafer after a dummy gate formation, consistent with an illustrative embodiment.

FIG. 5D is a top view identifying the cross-sectional views of FIGS. 5A, 5B, and 5C, consistent with an illustrative embodiment.

FIGS. 6A, 6B, and 6C are cross-sectional views of the wafer after SiGe55 removal, consistent with an illustrative embodiment.

FIG. 6D is a top view identifying the cross-sectional views of FIGS. 6A, 6B, and 6C, consistent with an illustrative embodiment.

FIGS. 7A, 7B, and 7C are cross-sectional views of a spacer formation operation.

FIG. 7D is a top view identifying the cross-sectional views consistent with an illustrative embodiment.

FIGS. 8A, 8B, and 8C are cross-sectional views of the wafer after an Optical Planarizing Layer coat and etch operation, consistent with an illustrative embodiment.

FIG. 8D is a top view identifying the cross-sectional views of FIGS. 8A, 8B, and 8C, consistent with an illustrative embodiment.

FIGS. 9A, 9B, and 9C are cross-sectional views showing removing exposed gate spacers, consistent with an illustrative embodiment.

FIG. 9D is a top view identifying the cross-sectional views of FIGS. 9A, 9B, and 9C, consistent with an illustrative embodiment.

FIGS. 10A, 10B, and 10C are cross-sectional views of forming a protective gate spacer, consistent with an illustrative embodiment.

FIG. 10D is a top view identifying the cross-sectional views of FIGS. 10A, 10B, and 10C, consistent with an illustrative embodiment.

FIGS. 11A, 11B, and 11C are cross-sectional views showing the Optical Planarizing Layer coat being stripped, consistent with an illustrative embodiment.

FIG. 11D is a top view identifying the cross-sectional views of FIGS. 11A, 11B, and 11C, consistent with an illustrative embodiment.

FIGS. 12A, 12B, and 12C are cross-sectional views of the spacer pull down at a sidewall of the nanosheets, consistent with an illustrative embodiment.

FIG. 12D is a top view identifying the cross-sectional views of FIGS. 12A, 12B, and 12C, consistent with an illustrative embodiment.

FIGS. 13A, 13B, and 13C are cross-sectional views of a nanosheet recess, SiGe indentation, and an inner space formation, consistent with an illustrative embodiment.

FIG. 13D is a top view identifying the cross-sectional views of FIGS. 13A, 13B, and 13C, consistent with an illustrative embodiment.

FIGS. 14A, 14B, and 14C are cross-sectional views of a placeholder trench patterning, consistent with an illustrative embodiment.

FIG. 14D is a top view identifying the cross-sectional views of FIGS. 14A, 14B, and 14C, consistent with an illustrative embodiment.

FIGS. 15A, 15B, and 15C are cross-sectional views of forming a placeholder material and recess, consistent with an illustrative embodiment.

FIG. 15D is a top view identifying the cross-sectional views of FIGS. 15A, 15B, and 15C, consistent with an illustrative embodiment.

FIGS. 16A, 16B, and 16C are cross-sectional views of forming the source/drain (S/D) epitaxial, interlayer dielectric (ILD) and a chemical mechanical planarization (CMP), and FIG. 16D is a top view identifying the cross-sectional views consistent with an illustrative embodiment.

FIGS. 17A, 17B, and 17C are cross-sectional views of a dummy gate removal, SiGe removal, and forming a replacement a High K Metal Gate (HKMG), consistent with an illustrative embodiment.

FIG. 17D is a top view identifying the cross-sectional views of FIGS. 17A, 17B, and 17C, consistent with an illustrative embodiment.

FIGS. 18A, 18B, and 18C are cross-sectional views of forming a Middle of Line (MOL) and a lower Back end of Line (BEOL), consistent with an illustrative embodiment.

FIG. 18D is a top view identifying the cross-sectional views of FIGS. 18A, 18B, and 18C, consistent with an illustrative embodiment.

FIGS. 19A, 19B, and 19C are cross-sectional views of forming additional Back end of Line levels and bonding a carrier wafer, consistent with an illustrative embodiment.

FIG. 19D is a top view identifying the cross-sectional views of FIGS. 19A, 19B, and 19C, consistent with an illustrative embodiment.

FIGS. 20A, 20B, and 20C are cross-sectional views of a wafer flip and Si substrate removal, consistent with an illustrative embodiment.

FIG. 20D is a top view identifying the cross-sectional views of FIGS. 20A, 20B, and 20C, consistent with an illustrative embodiment.

FIGS. 21A, 21B, and 21C are cross-sectional views of forming a dielectric capping, consistent with an illustrative embodiment.

FIG. 21D is a top view identifying the cross-sectional views of FIGS. 21A, 21B, and 21C, consistent with an illustrative embodiment.

FIGS. 22A, 22B, and 22C are cross-sectional views of a sacrificial placeholder removal, consistent with an illustrative embodiment.

FIG. 22D is a top view identifying the cross-sectional views of FIGS. 22A, 22B, and 22C, consistent with an illustrative embodiment.

FIGS. 23A, 23B, and 23C are cross-sectional views of a selective interlayer dielectric (ILD) etch and capping dielectric, consistent with an illustrative embodiment.

FIG. 23D is a top view identifying the cross-sectional views of FIGS. 23A, 23B, and 23C, consistent with an illustrative embodiment.

FIGS. 24A, 24B, and 24C are cross-sectional views of a backside contact metallization, consistent with an illustrative embodiment.

FIG. 24D is a top view identifying the cross-sectional views of FIGS. 24A, 24B, and 24C, consistent with an illustrative embodiment.

FIGS. 25A, 25B, and 25C are cross-sectional views of using a block mask to recess backside contact, consistent with an illustrative embodiment.

FIG. 25D is a top view identifying the cross-sectional views of FIGS. 25A, 25B, and 25C, consistent with an illustrative embodiment.

FIGS. 26A, 26B, and 26C are cross-sectional views of the semiconductor device after an ILD deposition, backside power rail formation, and a backside power distribution network (BSPDN) formation, consistent with an illustrative embodiment.

FIG. 26D is a top view identifying the cross-sectional views of FIGS. 26A, 26B, and 26C.

FIGS. 27A, 27B, and 27C illustrate three semiconductor devices consistent with illustrative embodiments.

### DETAILED DESCRIPTION

### Overview

In the following detailed description, numerous specific details are set forth by way of examples to provide a thorough understanding of the relevant teachings. However, it should be understood that the present teachings may be practiced without such details. In other instances, well-known methods, procedures, components, and/or circuitry have been described at a relatively high level, without detail, to avoid unnecessarily obscuring aspects of the present teachings. It is to be understood that the present disclosure is not limited to the depictions in the drawings, as there may be fewer elements or more elements than shown and described.

In discussing the present technology, it may be helpful to describe various salient terms. In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other directions) and the spatially relative descriptors used herein should be interpreted accordingly.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, third, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

### Example Architecture

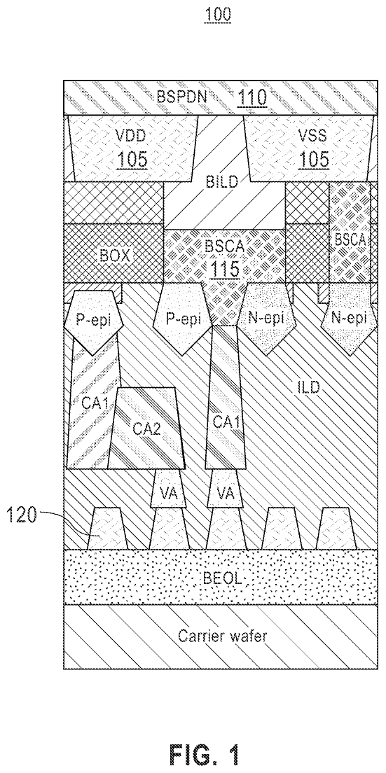

FIG. 1 illustrates an overview 100 of a local interconnect at the backside for flexible routing across difference cells consistent with an illustrative embodiment. A backside power distribution network BSPDN 110 is connected to power rails 105 (VSS and VDD). A backside local interconnect includes at least two Source/Drain (S/D) epi regions (FIG. 1 P-epi and N-epi) connected together through a backside contact (BSCA) 115 that has a recessed surface that does not contact the power rails 105. The backside local interconnect is wired to frontside signal wires 120 through a frontside contact CA1. At least an S/D epi region with the BSCA 115 is overlapped with a frontside contact extension CA2 of a device from a neighboring cell.

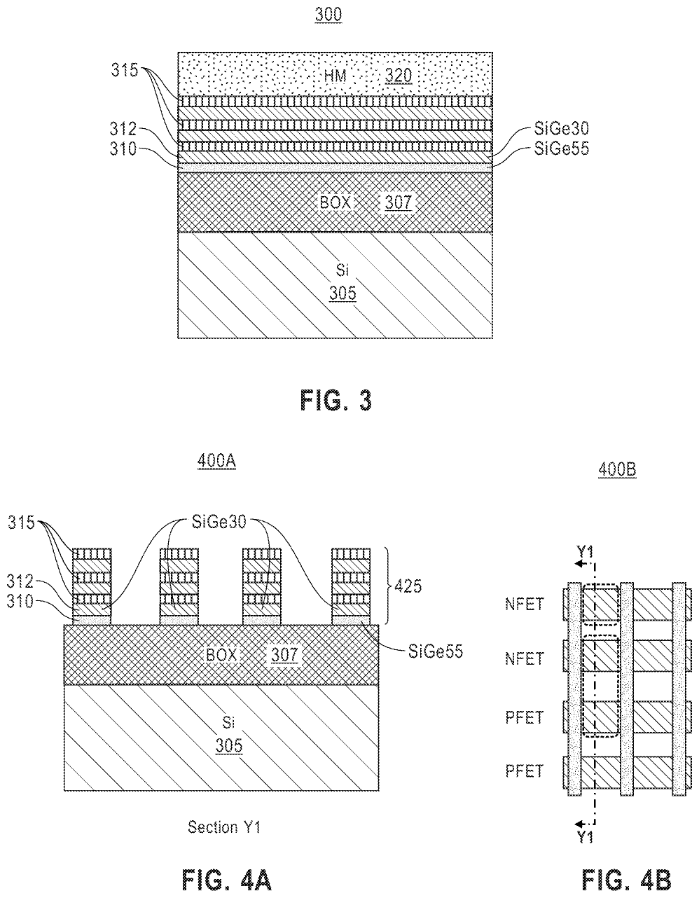

An example process of the construction of the semiconductor device shown in FIGS. 3 to 26.

### Example Process

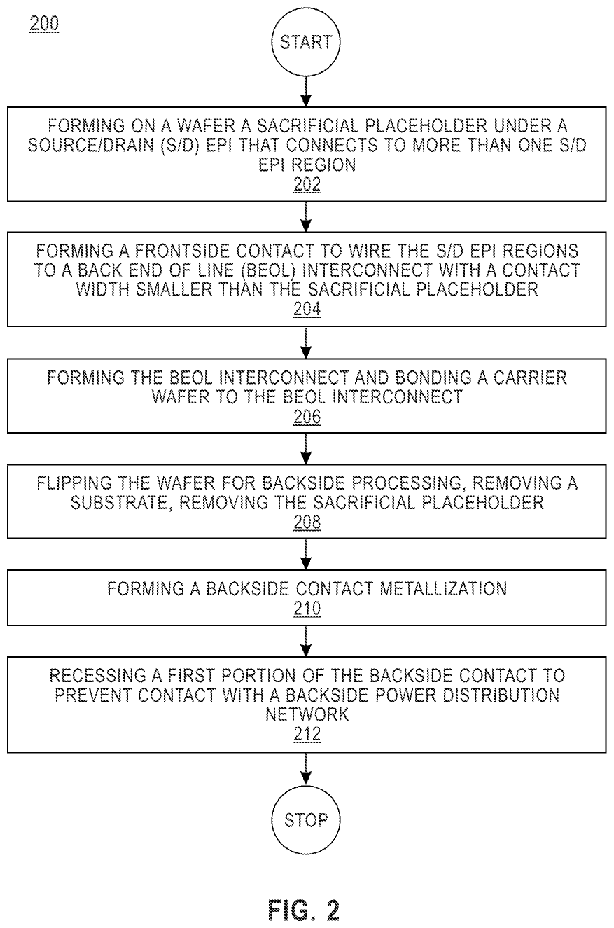

With the foregoing overview of the example architecture, it may be helpful now to consider a high-level discussion of an example process. To that end, FIG. 2 is a flowchart illustrating a method of forming a semiconductor device, consistent with an illustrative embodiment.

FIG. 2 is shown as a collection of blocks, in a logical order, which represents a sequence of operations that can be implemented in hardware, software, or a combination thereof. In each process, the order in which the operations are described is not intended to be construed as a limitation, and any number of the described blocks can be combined in any order and/or performed in parallel to implement the process. Some of the drawings in conjunction with the process flow of FIGS. 3-26 will be referenced to illustrate some of the operations of in FIG. 2.

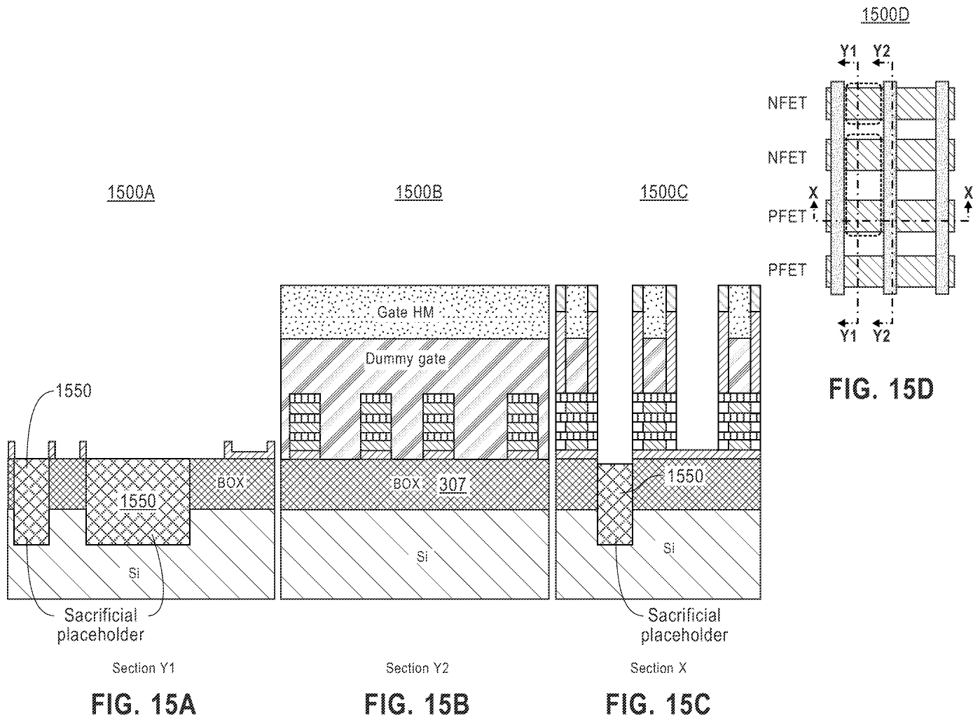

At operation 202, a sacrificial placeholder is formed on a wafer under a Source/Drain (S/D) epitaxial (epi) region that connects to more than one S/D epi region. FIGS. 15A and 15C show a sacrificial placeholder 1550 that is arranged in a trench area.

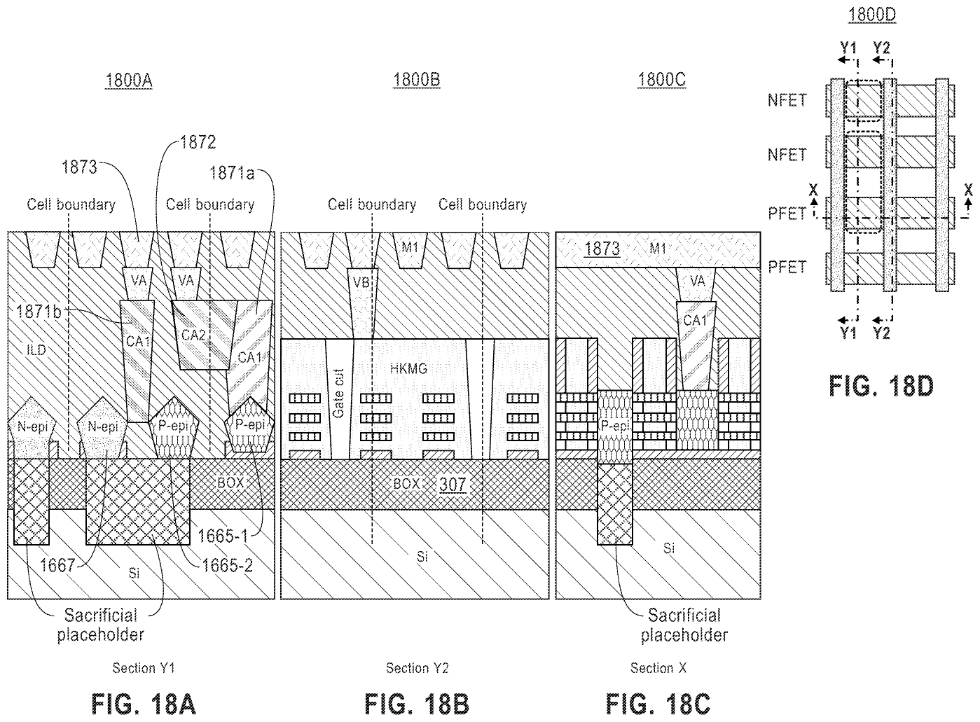

At operation 204, a frontside contact is formed to wire S/D epi regions to a BEOL interconnect with a contact width smaller than the sacrificial placeholder. FIG. 18A shows the frontside contact CA1 1871b.

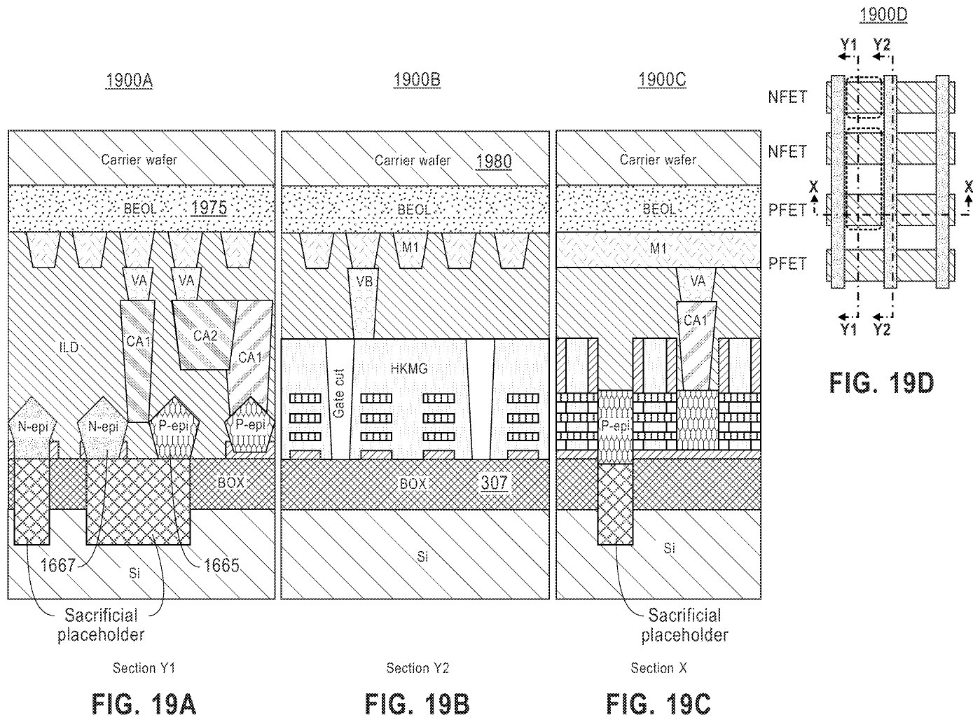

At operation 206, a BEOL interconnect is formed and a carrier wafer is bonded to the BEOL interconnect. FIG. 19A shows the BEOL 1975 and the carrier wafer 1980. The carrier wafer 1980 is used to flip the wafer for the backside fabrication process.

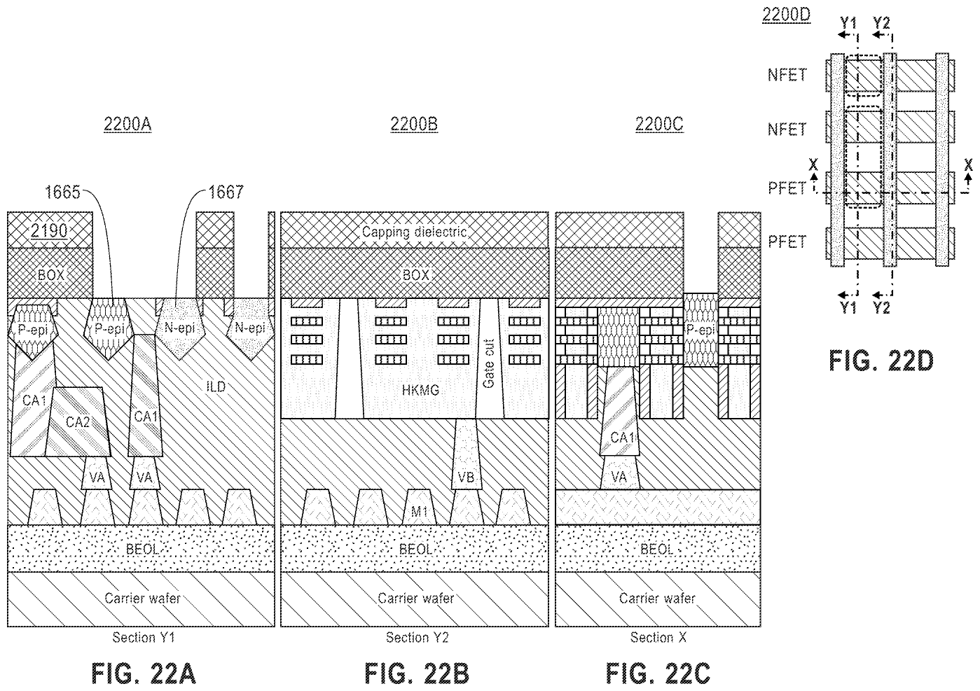

At operation 208, the wafer is flipped, and the substrate and sacrificial placeholder are removed. FIG. 22A shows the wafer is flipped, and the sacrificial placeholder material has been removed.

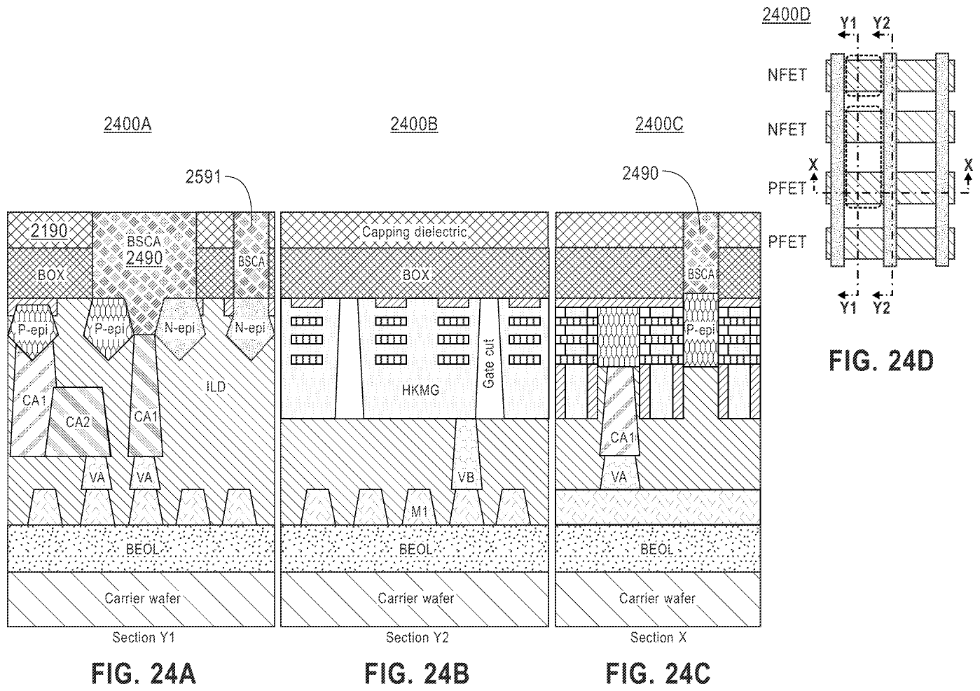

At operation 210, a backside contact (BSCA) metallization layer is formed. Referring to FIGS. 24A and 24C, the BSCA 2490 is shown filling in where the sacrificial placeholder was removed.

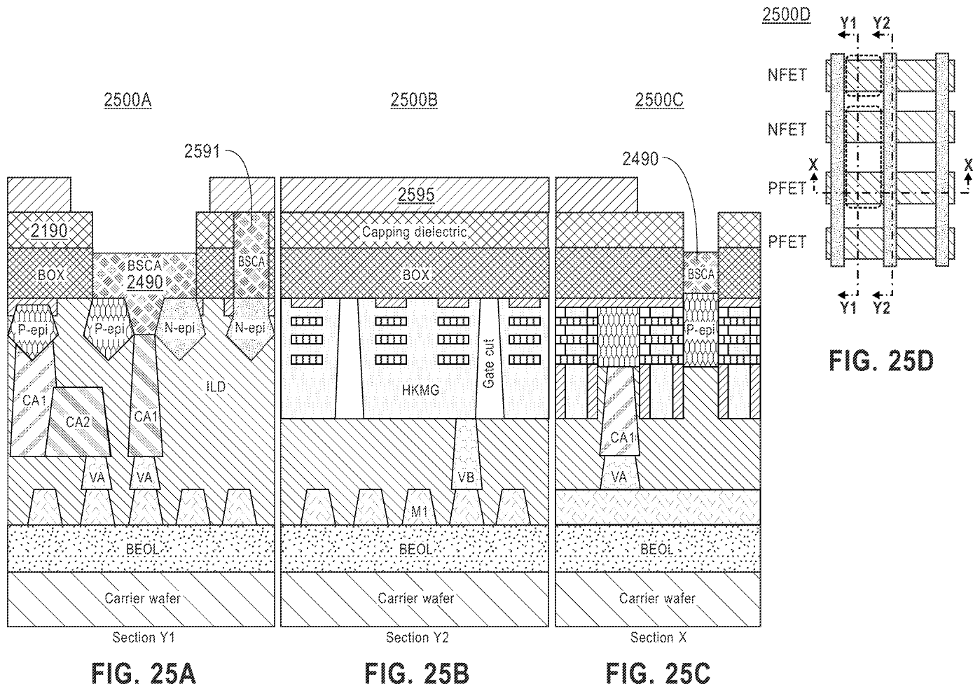

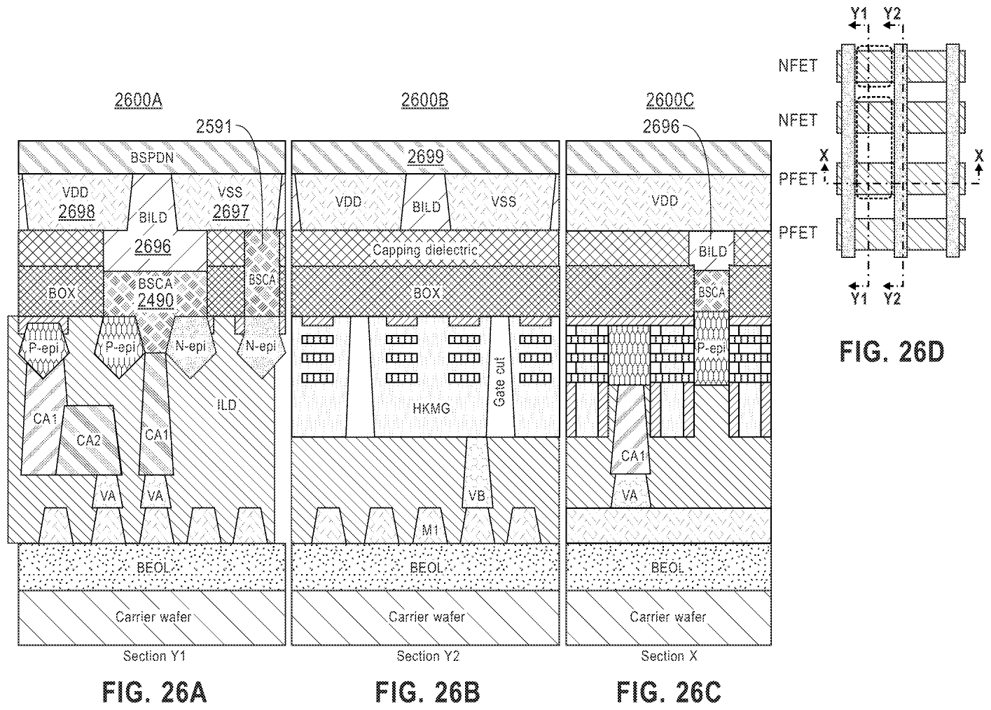

At operation 212, a first portion of the BSCA is recessed to prevent contact shorting with a backside power rail and a power distribution network. Referring to FIG. 25A, it is shown that the BSCA 2490 has been recessed so that its height is lower than the height of the BSCA 2591. Referring to FIG. 26A, it is shown that the BSCA 2490 does not contact the backside power rail or the power distribution network. However, the BSCA 2591, which was not etched, is in contact with the power rail VSS 2697.

With regard to the method described above in the flowchart of FIG. 2, it will be understood that this embodiment is not exhaustive of the scope of the disclosure. For example, the process flow of FIGS. 3 to 26 discloses additional operations that may be performed in the fabrication of the semiconductor device according to the various illustrative embodiments.

FIGS. 3-26 are process flows illustrating a fabrication method consistent with an illustrative embodiment. A discussion of the entire process flow is provided herein below.

FIG. 3 illustrates a starting wafer used in a method of forming a semiconductor, consistent with an illustrative embodiment. There is shown a starting wafer 300 having a substrate 305, which may be any foundation that can be used to build the present structures discussed herein, such as silicon (Si), and a buried oxide (BOX) layer 307. However, it is to be understood that the substrate is not limited to Si, which is disclosed for illustrative purposes. A nanosheet is stacked on top of the starting wafer and includes a SiGe55 layer 310, SiGe30 layers 312, and Si layers 315 alternately arranged. A hard mask (HM) 320 is arranged on top of the stacked layers of the starting wafer 300.

FIG. 4A illustrates a cross-sectional view 400A of a nanosheet patterning and hard mask removal from the wafer, and FIG. 4B shows a top view 400B of identifying the cross-section (Y1) shown in FIG. 4A, consistent with an illustrative embodiment. It can be seen that the HM 320 (shown in FIG. 3) has been removed, and there are nanosheet patterns 425.

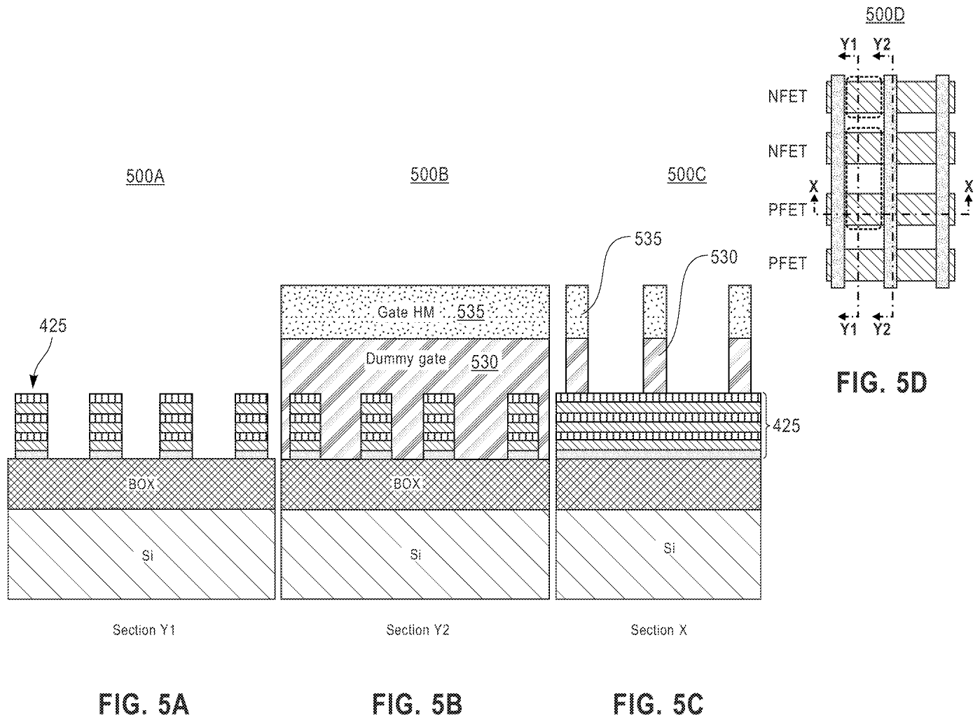

FIGS. 5A, 5B, and 5C are cross-sectional views 500ABC of the wafer after dummy gate formation, and FIG. 5D is a top view 500D identifying the cross-sectional views, consistent with an illustrative embodiment. FIG. 5A shows the “Y1” section, which is the same as shown in FIG. 4A. FIG. 5B shows a cross section “Y2” along a dummy gate 530 and a gate hard mask (HM) 535 material arranged on the wafer. FIG. 5C shows the “X” cross-section along the active nanosheet region, and it is orthogonal to the dummy gate 530 and HM 535. The dummy gate materials and HM are firstly deposited using conventional ALD, CVD or PVD depositions, followed by conventional gate patterning by lithography and an etch process.

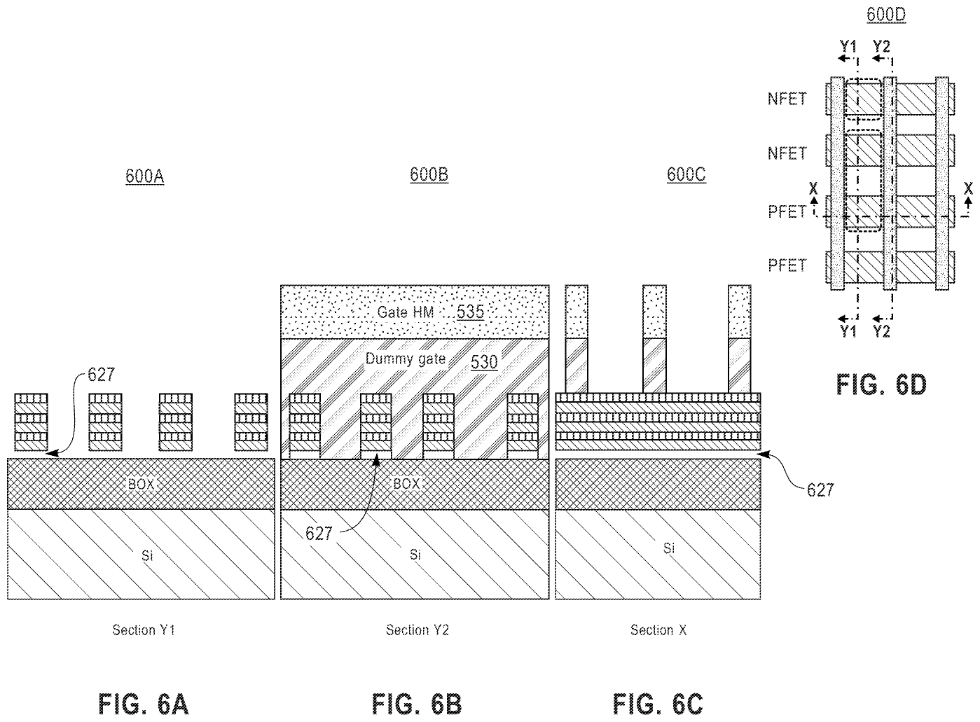

FIGS. 6A, 6B, and 6C are cross-sectional views 600ABC of the wafer after SiGe55 removal, and FIG. 6D is a top view 600D identifying the cross-sectional views of FIGS. 6A, 6B, and 6C consistent with an illustrative embodiment. The SiGe55 layer is removed as identified by the spaces 627 in FIGS. 6A, 6B, and 6C.

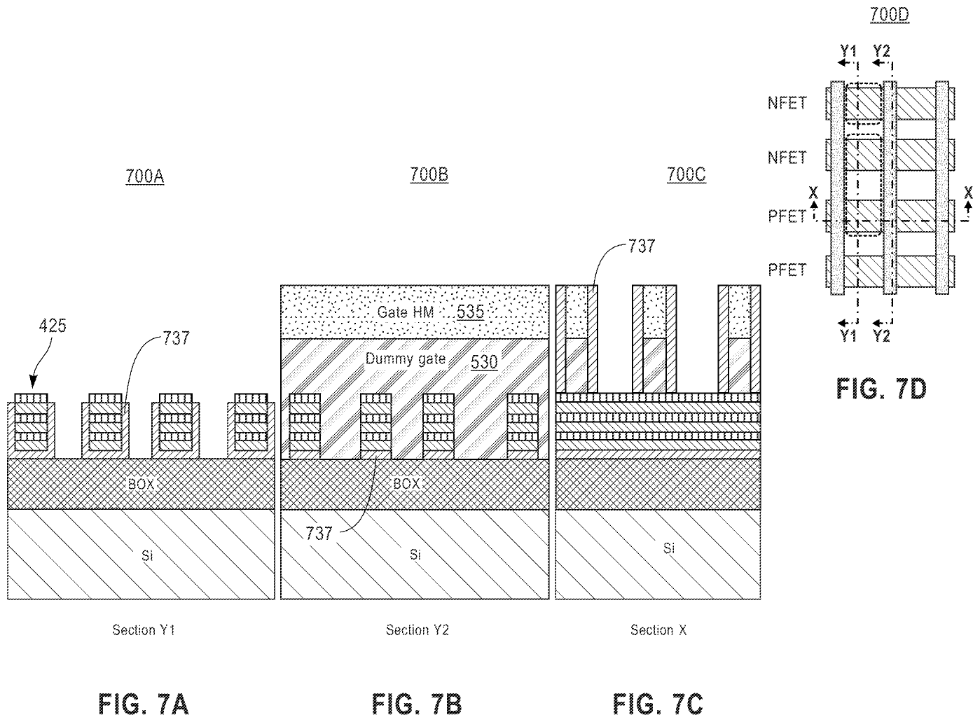

FIGS. 7A, 7B, and 7C are cross-sectional views 700ABC of a spacer formation operation, and FIG. 7D is a top view 700D identifying the cross-sectional views, consistent with an illustrative embodiment. It is shown that spacer material 737 fills in both the portions of the SiGe55 that were removed, and additionally the dummy gate 530 surrounds part of the nanosheet patterns 425, and gate HM 535. The spacer 737 is formed by conformal dielectric liner deposition and an anisotropic dry etch process.

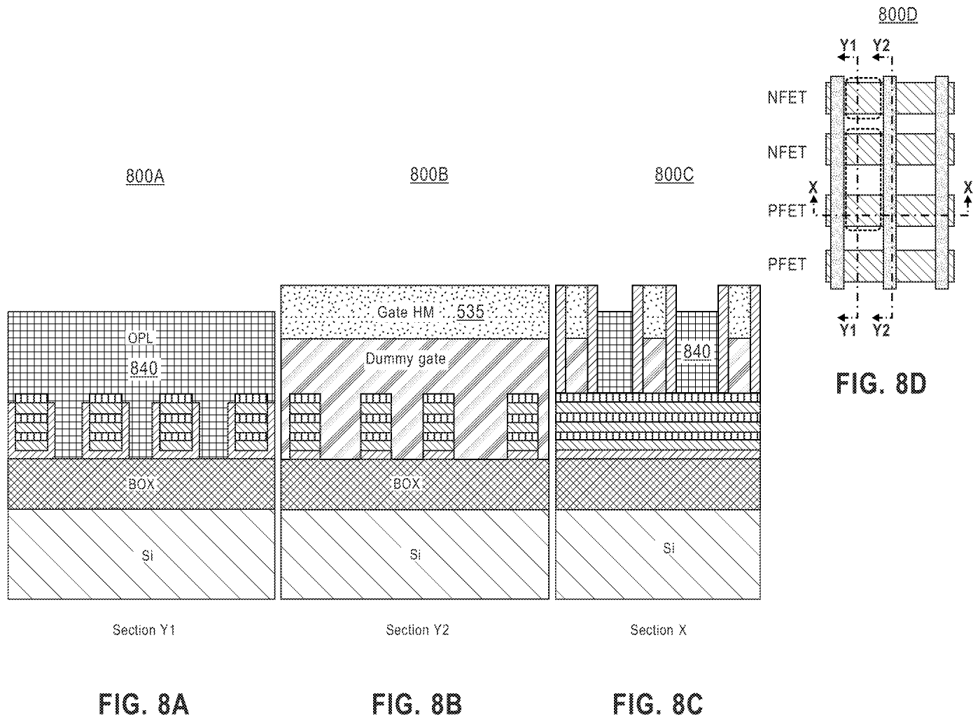

FIGS. 8A, 8B, and 8C are cross-sectional views 800ABC of the wafer after an Optical Planarizing Layer coat (OPL) and etch back operation, and FIG. 8D is a top view 800D identifying the cross-sectional views of FIGS. 8A, 8B, and 8C, consistent with an illustrative embodiment. The OPL 840 is coated around the nanosheets 425, and is recessed such that a top portion of the gate spacer 737 is exposed while spacer 737 at sidewall of nanosheets 425 is fully covered, particularly as shown in FIGS. 8A and 8C.

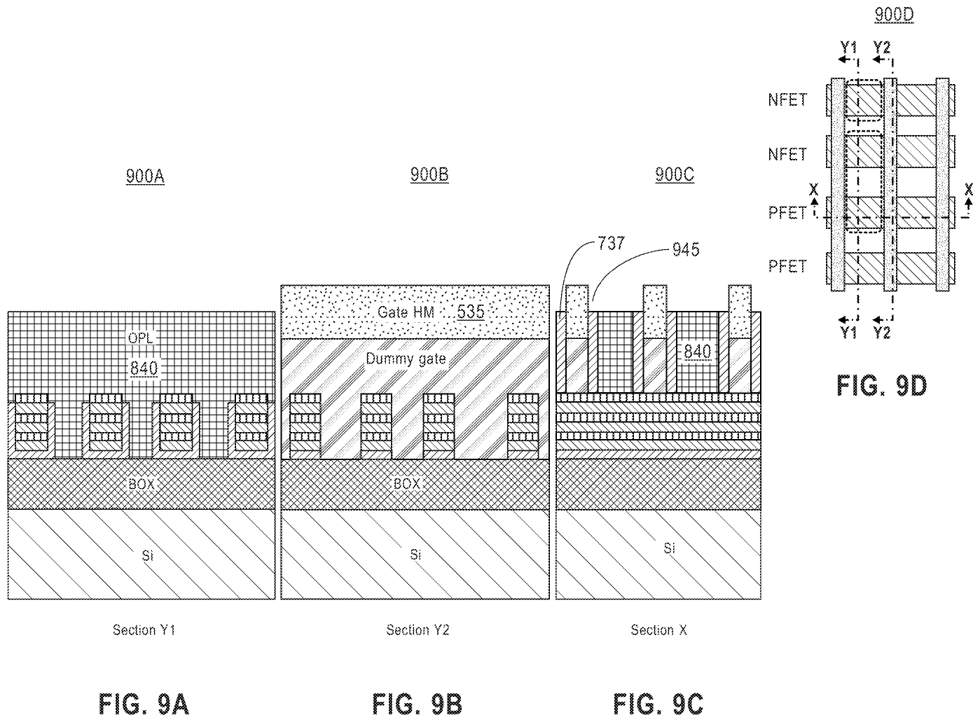

FIGS. 9B, 9B, and 9C are cross-sectional views 900ABC of the wafer illustrating the removal of exposed gate spacers, consistent with an illustrative embodiment. FIG. 9D is a top view 900D identifying the cross-sectional views of FIGS. 9A, 9B, and 9C. As shown in FIG. 9C, the spacer 737 is etched back leaving an exposed portion 945 of the gate HM.

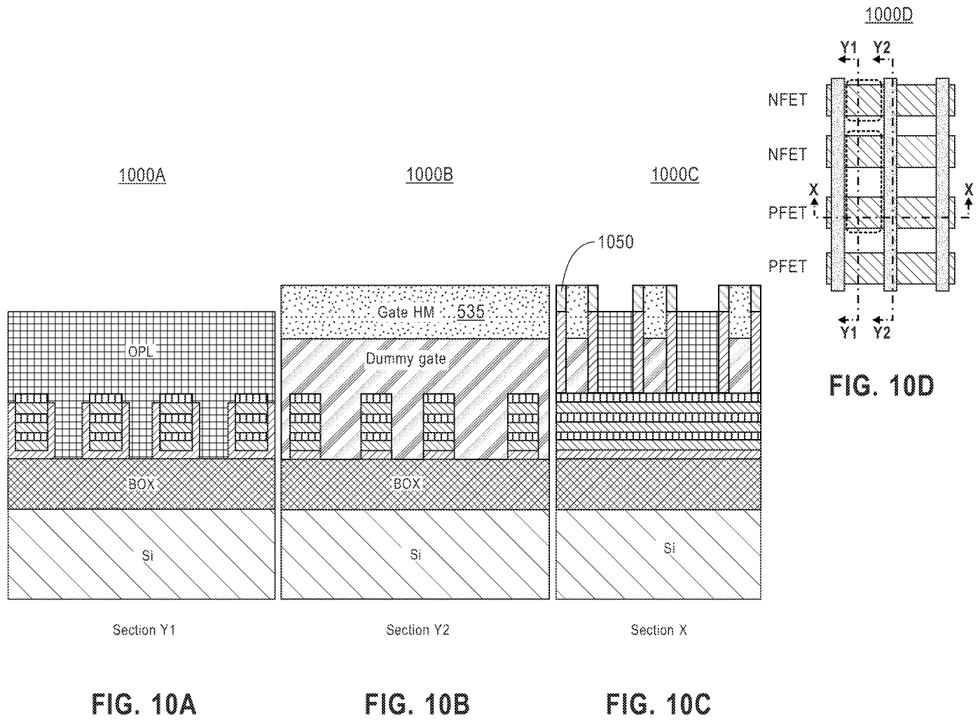

FIGS. 10A, 10B, and 10C are cross-sectional views 1000ABC showing the forming of a protective gate spacer, consistent with an illustrative embodiment. FIG. 10D is a top view 1000D identifying the cross-sectional views of FIGS. 10A, 10B, and 10C. It is shown particularly in FIG. 10C that a protective gate spacer 1050 has been arranged around upper portions of the gate HM 535 to protect the gate spacer 737 in subsequent spacer pull down process.

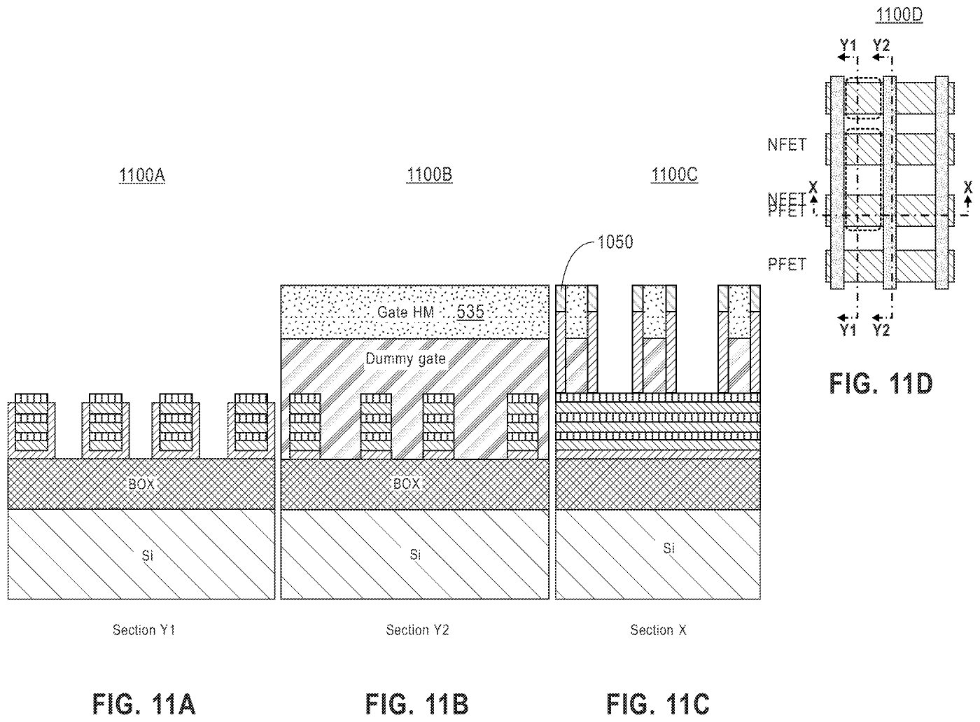

FIGS. 11A, 11B, and 11C are cross-sectional views 1100ABC showing the OPL is stripped, consistent with an illustrative embodiment. FIG. 11D is a top view 1100D identifying the cross-sectional views of FIGS. 11A, 11B, and 11C. The OPL Layer 840 (shown in FIG. 8) is stripped off, leaving the nanosheets 425, dummy gate 530, gate HM 535 and the protective gate spacer 1050.

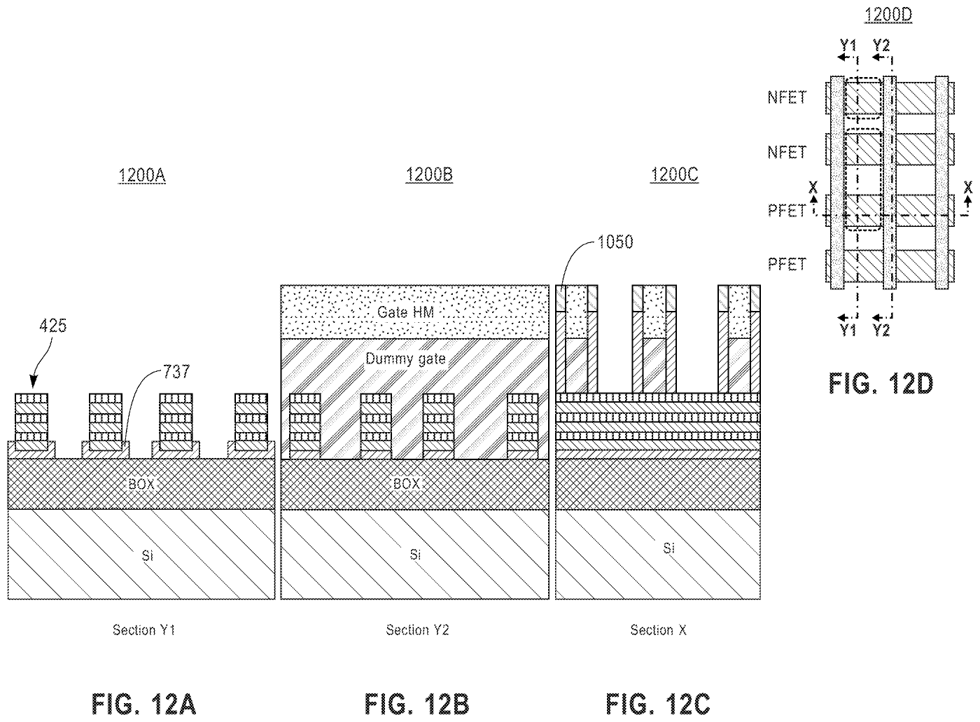

FIGS. 12A, 12B, and 12C are cross-sectional views illustrating the spacer pull down at a sidewall of the nanosheets, consistent with an illustrative embodiment. FIG. 12D is a top view 1200D identifying the cross-sectional views of FIGS. 12A, 12B, and 12C. Compared with FIG. 7, the spacer material 737 is no longer present along the sidewalls of the nanosheets 425, but remains along the surface of the wafer.

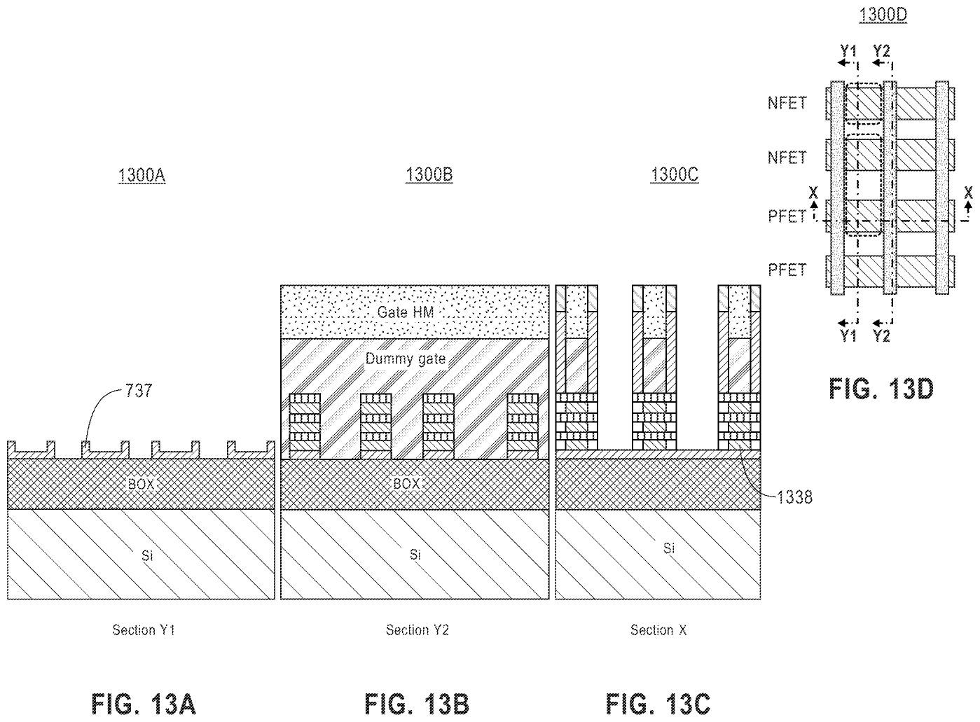

FIGS. 13A, 13B, and 13C are cross-sectional views 1300ABC illustrating a nanosheet recess, SiGe indentation, and an inner spacer formation, consistent with an illustrative embodiment. FIG. 13D is a top view 1300D identifying the cross-sectional views of FIGS. 13A, 13B, and 13C. FIG. 13C in particular shows the nanosheets have been recessed (as compared with FIG. 12C), and forming an inner spacer 1338.

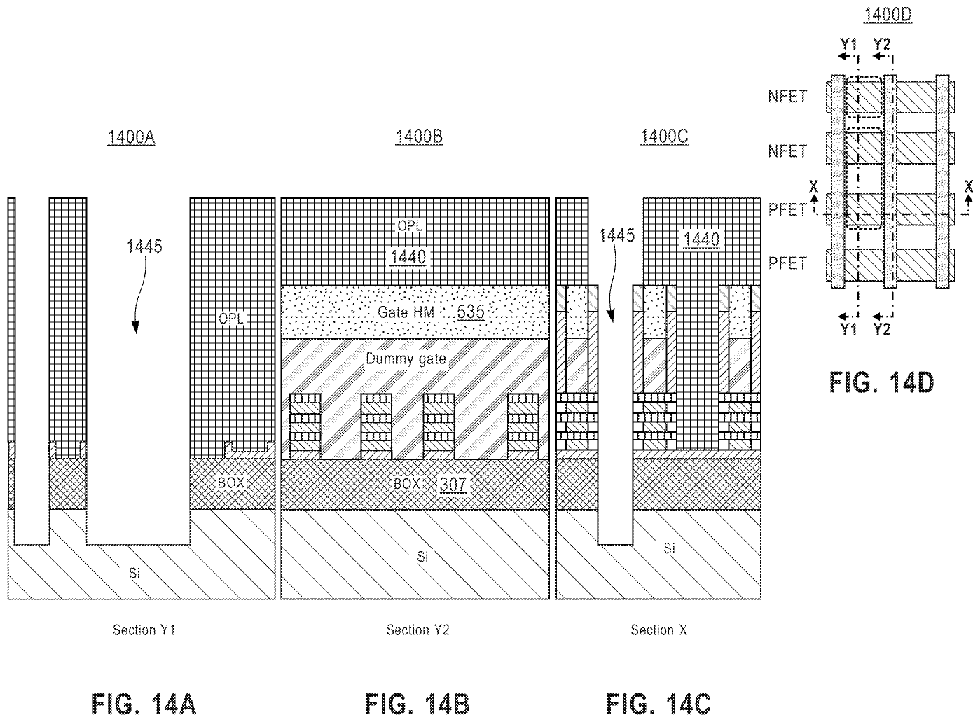

FIGS. 14A, 14B, and 14C are cross-sectional views of a placeholder trench patterning, consistent with an illustrative embodiment. FIG. 14D is a top view 1400D identifying the cross-sectional views of FIGS. 14A, 14B, and 14C. Trenches 1445 are shown in views FIGS. 14A and 14C to define backside contacts. A masking layer 1440, such as an OPL layer is coated and patterned by conventional lithography and a dry etch process, followed by trench formation by etching into the bottom dielectric isolation layer, a BOX into the substrate Si, selective to the protective gate spacer 1050, to minimize the damage to the dummy gate or gate spacer.

FIGS. 15A, 15B, and 15C are cross-sectional views of forming a placeholder material and recess, consistent with an illustrative embodiment. FIG. 15D is a top view 1500D identifying the cross-sectional views of FIGS. 15A, 15B, and 15C. A sacrificial material 1550 (e.g., a material including but not limited to SiGe, AlOₓ, TiOₓ, etc.) is arranged in the trench areas 1445 (shown in FIG. 14A, 14C). The OPL material 1440 (shown in FIGS. 14A-14C) is removed.

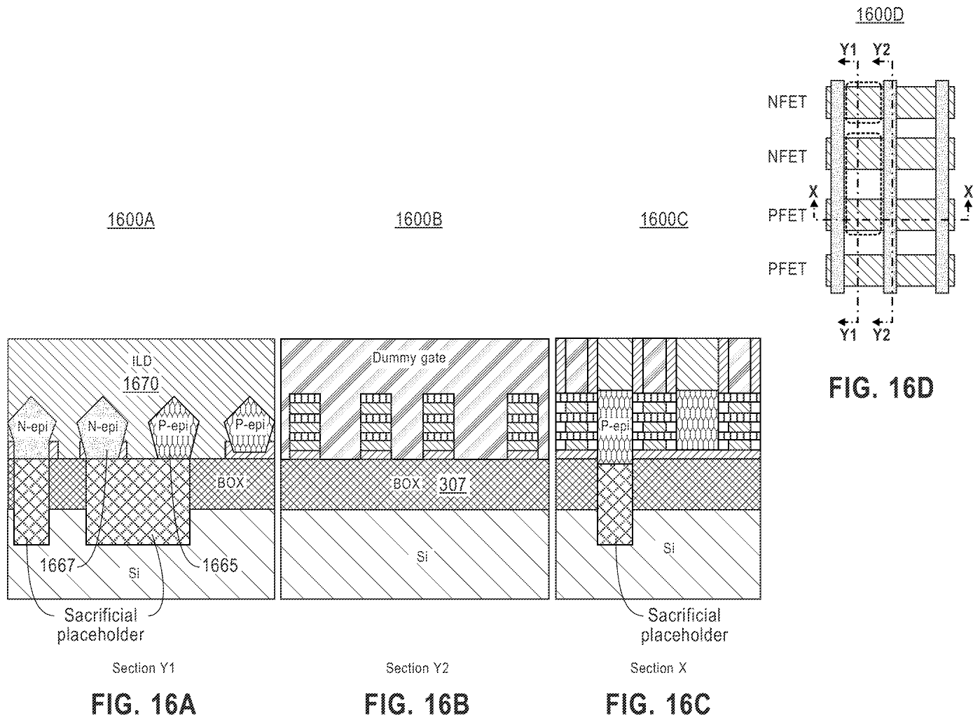

FIGS. 16A, 16B, and 16C are cross-sectional views 1600ABC of forming the S/D epi, ILD and CMP, consistent with an illustrative embodiment. FIG. 16D is a top view 1600D identifying the cross-sectional views of FIGS. 16A, 16B, and 16C. It can be seen that the gate HM shown in FIGS. 15B, and 15C is removed, as well as the upper portion of the protective spacer in FIG. 15C. The S/D P-epi 1665, N-epi 1667 are formed on the sacrificial material 1550. As shown in FIGS. 16A and 16C, the interlayer dielectric (ILD) layer 1670 is then formed, and chemical mechanical planarization (CMP) and polishing of the ILD 1670 is performed.

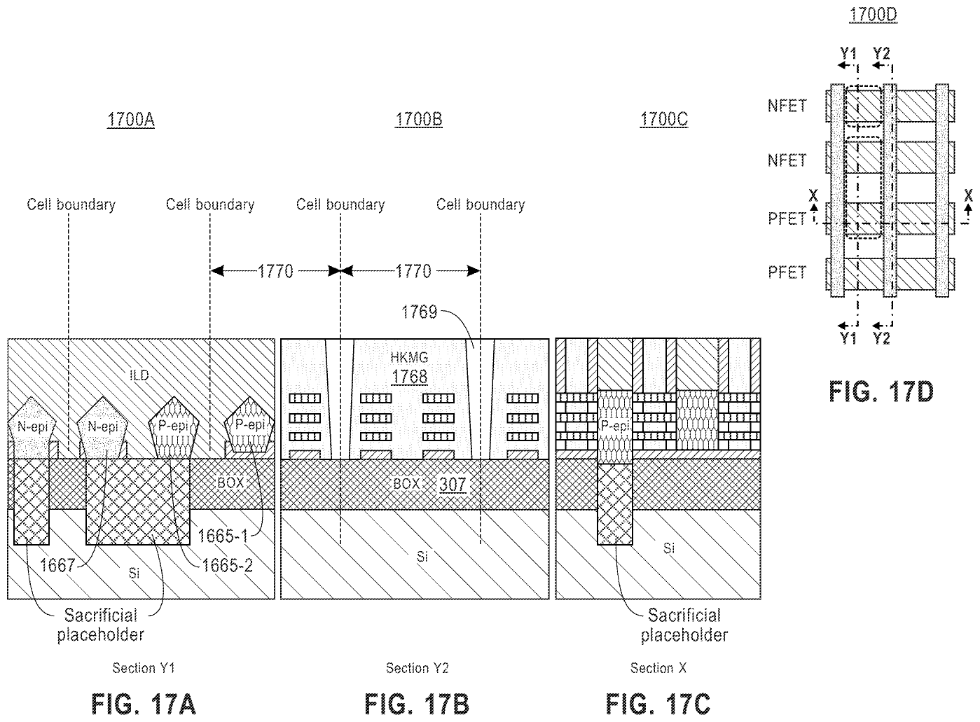

FIGS. 17A, 17B, and 17C are cross-sectional views 1700ABC of operations of a dummy gate removal, SiGe removal and forming a replacement HKMG, consistent with an illustrative embodiment. FIG. 17D is a top view 1700D identifying the cross-sectional views of FIGS. 17A, 17B, and 17C. The dummy gate is removed and replaced with a High K Metal Gate (HKMG) 1768, and gate cut regions 1769 are made. There are cell boundaries 1770 shown, with the dashed vertical lines indicating the neighboring cells.

FIGS. 18A, 18B, and 18C are cross-sectional views 1800ABC of forming a Middle of Line (MOL) and a lower back end of line (BEOL), consistent with an illustrative embodiment. FIG. 18D is a top view 1800D identifying the cross-sectional views of FIGS. 18A, 18B, and 18C. referring to section Y1 in FIG. 18A, the contact CA2 1872 is arranged across two cell boundaries, which enables access to signal lines from a neighboring cell. For example, the P-epi 1665-1 has an electrical path to CA1 1871a, to CA2 1872, and to the metal line M1 1873, which is for example, a signal line in a neighboring cell boundary (as the boundary is demarcated with the vertically-dashed line). Another contact CA 1871b provides an additional path to another one of the metal lines M1 from the N-epi 1667 and P-epi 1665-2. The width of the contact CA 1871b is narrower than a conventional contact, but is sufficiently wide to provide a connection to both the N-epi 1667 and P-epi 1665-2. The reduced width of the contact CA2 1871b enables the access of the metal line M1 1873 by the P-epi 1665-1 in the neighboring cell.

FIGS. 19A, 19B, and 19C are cross-sectional views 1900ABC of forming additional BEOL levels and bonding a carrier wafer, consistent with an illustrative embodiment. FIG. 19D is a top view 1900D identifying the cross-sectional views of FIGS. 19A, 19B, and 19C. The back end of line (BEOL) 1975 layers are attached to the wafer, and the carrier wafer 1980 is bonded to the BEOL 1975. The carrier wafer is used perform a wafer flip, to perform additional processing such as backend processing.

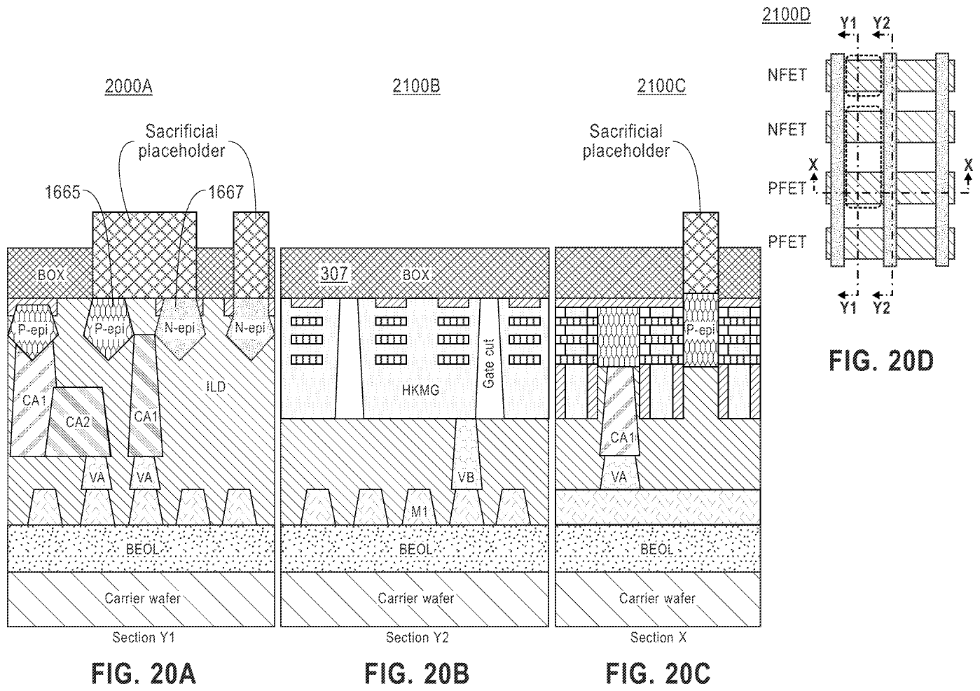

FIGS. 20A, 20B, and 20C are cross-sectional views 2000ABC of a wafer flip and Si substrate removal, consistent with an illustrative embodiment. FIG. 20D is a top view 2000D identifying the cross-sectional views of FIGS. 20A, 20B, and 20C. As shown in FIGS. 20A, 20B, and 20C, the wafer has been flipped for backside processing. The carrier wafer 1980 is typically used to flip the wafer for the additional processing. The Si substrate is removed leaving the BOX layer 307.

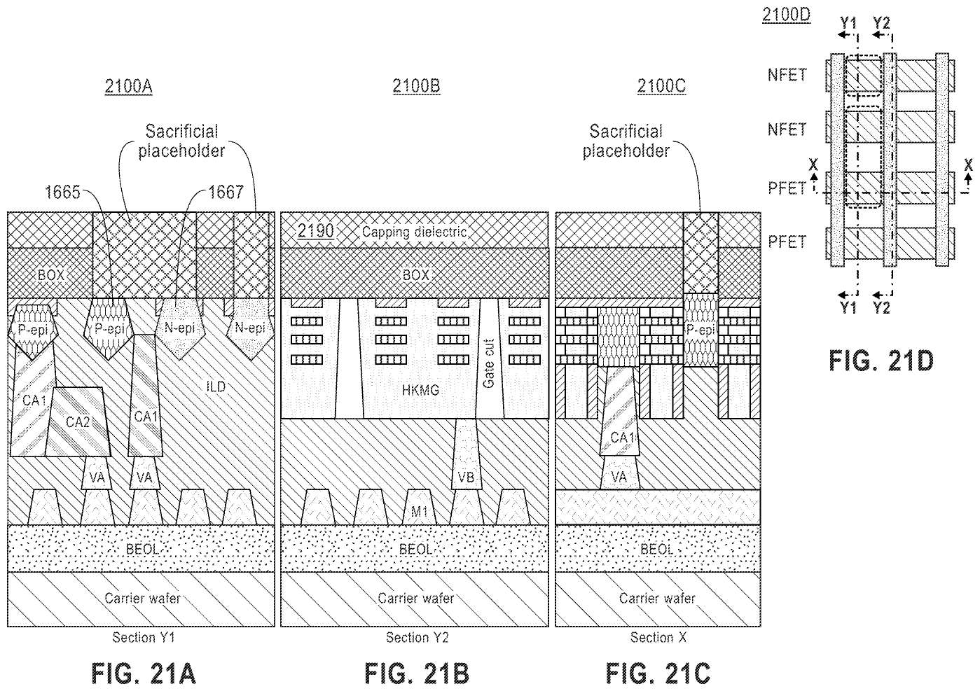

FIGS. 21A, 21B, and 21C are cross-sectional views 2100ABC of forming a dielectric capping, and FIG. 21D is a top view identifying the cross-sectional views consistent with an illustrative embodiment. A capping dielectric layer 2190 is formed on the BOX layer 307. The capping layer may be a different dielectric than the ILD layer 1670 and BOX SiO2 307, and may enables subsequent etching of ILD 1670 without damaging the dielectric capping layer 2190. Some non-limiting examples of the capping dielectric material may be SiN, SiBCN, SiOCN, SiOc, SiC, etc.

FIGS. 22A, 22B, and 22C are cross-sectional views 2200ABC of a sacrificial placeholder removal, and FIG. 22D is a top view identifying the cross-sectional views consistent with an illustrative embodiment. It is shown that the sacrificial placeholder has been removed.

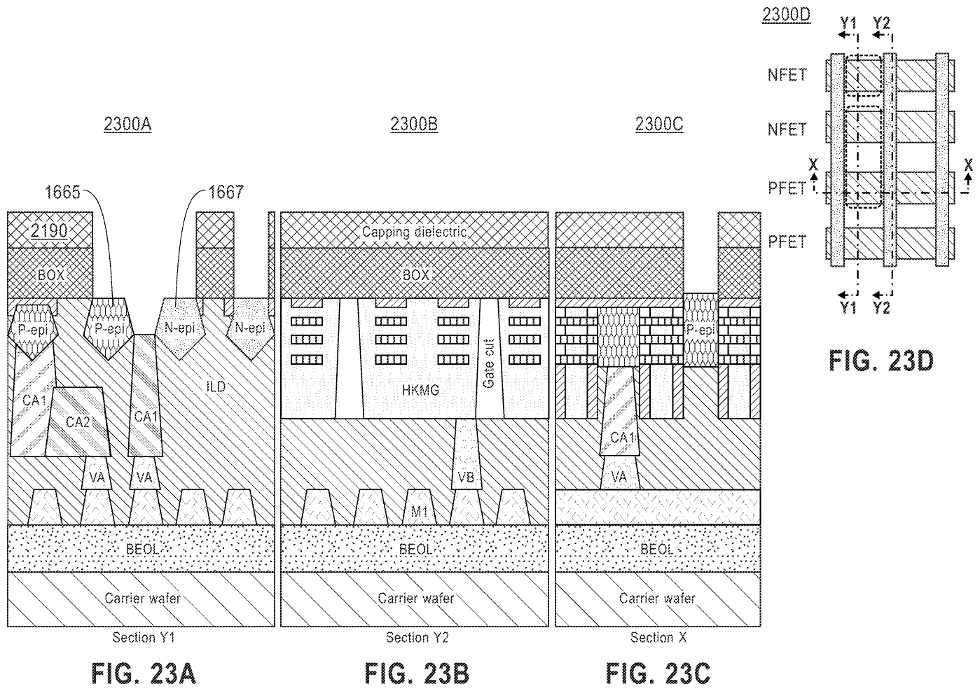

FIGS. 23A, 23B, and 23C are cross-sectional views 2300ABC of a selective etching of ILD layer 1670, with respect to the capping dielectric 2190, and FIG. 23D is a top view identifying the cross-sectional views consistent with an illustrative embodiment. An oxide etch is performed to remove the oxide between the P-epi 1665 and N-epi 1667, and open an electrical connection to the contact CA1 1871.

FIGS. 24A, 24B, and 24C are cross-sectional views 2400ABC of a backside contact metallization, and FIG. 24D is a top view identifying the cross-sectional views consistent with an illustrative embodiment. The backside contact BSCA for a local interconnect 2490 is filled in between the N-epi and P-epi, and will be recessed back (as shown in FIG. 25A and FIG. 25C).

FIGS. 25A, 25B, and 25C are cross-sectional views 2500ABC of using a block mask to recess a backside contact, and FIG. 25D is a top view identifying the cross-sectional views consistent with an illustrative embodiment. A portion of the BSCA 2490, 2491a is etched back below the capping dielectric 2190, and will be used as a local interconnect because the BSCA 2490 will not be connected to a backside power rail (as subsequently shown in FIG. 26A). A block mask 2595 is formed to recess the backside contact that is not connected to a backside power rail. Another portion of the BSCA 2491 is not etched back, as it will be used to connect to a power rail (shown in FIG. 26).

FIGS. 26A, 26B, and 26C are cross-sectional views 2600ABC of the semiconductor device after a backside ILD deposition, a backside power rail formation, and a backside power distribution network (BSPDN) formation, consistent with an illustrative embodiment. FIG. 26D is a top view identifying the cross-sectional views of FIGS. 26A, 26B, and 26C. The backside ILD (BILD) 2696 is filled in the portions where the BSCA 2490 was etched back to form a recess. The etched back BSCA 2490 is considered a local interconnect, as its function is to connect the source/drain regions from more than two different devices, and in this case, the local interconnect (recessed BSCA 2490) connects the N-epi and P-epi of two different devices, which in turn are in contact with CA1 and to the signal lines M1. In contrast to the local interconnect, the BSCA 2491 is connected to the power rail VSS 2697. The backside power distribution network (BDPSN) 2699 is attached to the power rails VSS 2697 and VDD 2698.

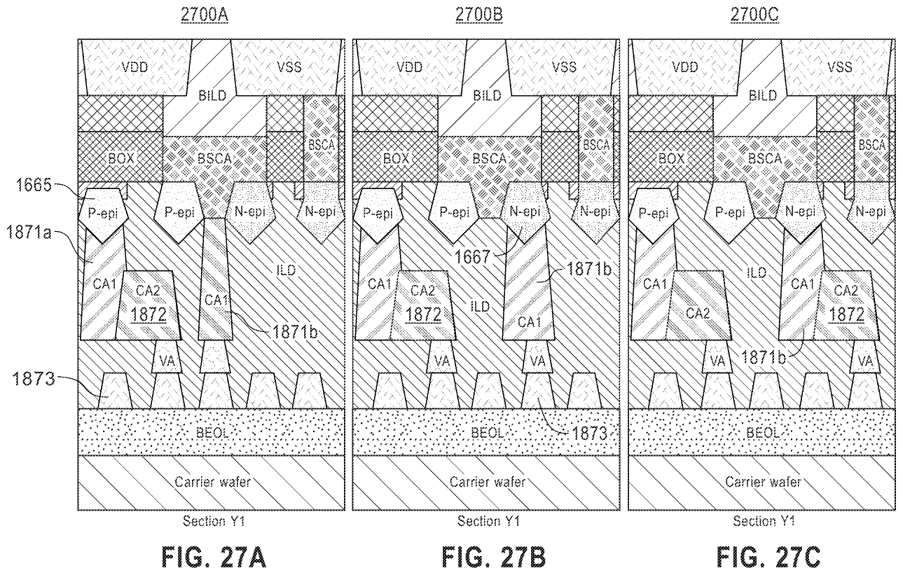

FIGS. 27A, 27B, and 27C illustrate three semiconductor devices consistent with illustrative embodiments. In FIG. 27A, structure is similar to that shown in FIGS. 25A, 25B, and 25C.

In FIG. 27A, the P-epi 1665 is connected to the metal line 1873 through the contact CA1 1871a and 1872. The P-epi 1665 and the adjacent P-epi and N-epi are connected through contact CA1 1871b to a different metal line, and the P-epi 1665 discussed above may be from an neighboring cell boundary.

In FIG. 27B, the contact CA1 1871b, which is wider than compared with the contact 1871b shown FIG. 27A. Still referring to FIG. 27B, the contact 1871b is connected to the N-epi 1667, whereas in FIG. 27A, the contact CA 1871b is connected to the BSCA.

In FIG. 27C, there is a second CA contact 1872 connected to the CA contact 1871b. The structure shown in 27C also enables neighboring cell boundaries to be used.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

The flowcharts, and diagrams in the figures herein illustrate the architecture, functionality, and operation of possible implementations according to various embodiments of the present disclosure.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device comprising:
a wafer having at least two source/drain (S/D) epi regions;
a power rail arranged on a backside of the wafer;
a backside contact (BSCA) having a first portion comprising a backside local interconnect with a recessed surface and is configured to connect the S/D epi regions together; and
a plurality of frontside signal wires connected to the backside local interconnect through a first front side contact.

2. The semiconductor device according to claim 1, wherein the BSCA comprises a second portion connected to the backside power rail.

3. The semiconductor device according to claim 1, wherein the recessed surface of the backside local interconnect is lower than a surface of the second portion of the BSCA to insulate the backside local interconnect from the backside power rail.

4. The semiconductor device according to claim 2, wherein a height of the recessed surface of the backside local interconnect is lower than a surface of a buried oxide (BOX) layer adjoining a side of the BSCA.

5. The semiconductor device according to claim 4, wherein the recessed surface of the backside local interconnect has a backside interlayer dielectric (BILD) formed thereon.

6. The semiconductor according to claim 1, wherein at least one S/D epi region connected to the backside local interconnect is overlapped with a second frontside contact extension of a device from a neighboring cell.

7. The semiconductor according to claim 6, wherein the second frontside contact extension is wired to signal tracks over the S/D region with the backside local interconnect.

8. The semiconductor according to claim 6, further comprising a backside power distribution network (BSPDN) connected to the backside power rail.

9. The semiconductor according to claim 1, wherein the at least one S/D epi region connected to the backside local interconnect comprises an S/D P-epi region and an S/D N-epi region.

10. The semiconductor device according to claim 8, wherein the S/D N-epi region or the S/D P-epi region is electrically connected to the frontside contact.

11. A method of forming a semiconductor device comprises:
forming, on a wafer, a sacrificial placeholder under a Source/Drain (S/D) epi that connects to more than one S/D epi region;
forming a frontside contact to wire the S/D epi regions to a Back End Of Line (BEOL) interconnect with a contact width smaller than the sacrificial placeholder;
forming the BEOL interconnect and a bonding a carrier wafer to the BEOL interconnect;
flipping the wafer, and removing a substrate;
removing the sacrificial placeholder; and
recessing a first portion of the backside contact to prevent contact with a backside power distribution network.

12. The method according to claim 11, further comprising connecting a second portion of the backside contact to a backside power rail connected to the backside power distribution network.

13. The method according to claim 12, further comprising recessing the first portion of the backside contact so its surface is lower than a surface of the second portion of the backside contact and insulated from the power rail, and the second portion of the backside contact is electrically connected to the backside power rail.

14. The method according to claim 13, further comprising forming a backside interlayer dielectric (BILD) on the recessed surface of the first portion of the backside contact.

15. The method according to claim 13, further comprising connecting at least one S/D epi region to overlap with a second frontside contact extension of a device from a neighboring cell.

16. The method according to claim 15, further comprising wiring the second frontside contact extension to signal tracks over the S/D region with the backside contact.

17. The method according to claim 15, further comprising connecting the backside power distribution network to the backside power rail.

18. The method according to claim 11, further comprising connecting the at least one S/D epi region to the backside contact local interconnect comprises connecting at least one of an S/D P-epi region and an S/D N-epi region.

19. The method according to claim 18, further comprising connecting one of the S/D N-epi region or the S/D P-epi region to the first frontside contact.

20. The method according to claim 11, further comprising forming a capping dielectric on the wafer after removing the sacrificial placeholder.
